(19) United States
(12) Patent Application Publication
(10) Pub. No.: US 2011/0226312 A1
(43) Pub. Date: Sep. 22, 2011

(54) VEHICLE SURFACE COMPONENT HAVING A SOLAR CELL ARRANGEMENT

(75) Inventors: Hubert Böhm, Greifenberg (DE); Andreas Lang, Grobenzell (DE); Steffen Lorenz, Landsberg/Lech (DE); Martin Pollak, Puchheim (DE); Michael Kölbl, Neuried (DE); Helmut Teschner, Landsberg/Lech (DE)

(73) Assignee: WEBASTO AG, Stockdorf (DE)

(21) Appl. No.: 13/057,823

(22) PCT Filed: Jan. 23, 2009
(86) PCT No.: PCT/EP09/00430

§ 371 Date: Jun. 1, 2011

(30) Foreign Application Priority Data
Aug. 12, 2008 (DE) 10 2008 038 647.2
Oct. 2, 2008 (DE) 10 2008 049 890.4

(51) Int. Cl. H01L 31/048

(52) U.S. Cl. 136/251

(57) ABSTRACT

The invention relates to a vehicle surface component, which can be attached to a vehicle in an exterior arrangement and has a solar cell arrangement, which is connected on its inner side to a carrying layer and is provided toward the outer side of the vehicle with an outer layer. A particularly light and stable vehicle surface component is obtained according to the invention by the carrying layer being produced in the manner of a composite lightweight construction.

The invention relates to a vehicle surface component having a solar cell arrangement according to the preamble of patent claim 1.

DE 10 2005 050 372 A1 discloses a vehicle surface component of this type which is formed from transparent plastic, is reinforced over the surface area by introduced reinforcing structures of metal and has a colored lacquer film applied on the interior side of the vehicle. Solar cells may be embedded between the plastic and the lacquer film or completely in the plastic. This vehicle surface component with internal solar cells consequently requires a transparent plastic as a carrier material.

DE 10 2004 003 856 A1 discloses a body part for a vehicle which is provided with a carrier layer and a solar module which is connected to the carrier layer and comprises at least one organic solar cell printed onto a film of plastic. The solar module may be applied to the side of the carrier layer facing the exterior side of the vehicle, it being possible for the printed film of plastic to be back-filled with the carrier layer or for the printed film of plastic to be adhesively bonded or laminated onto the carrier layer. If the carrier layer is at least partially transparent, the solar module may also be applied to the inwardly facing side of the carrier layer. The carrier layer may be produced from different plastics and also by means of the long fiber injection process (LFI process).

DE 101 01 770 A1 discloses a solar module in which the front side consists of a transparent polyurethane and the rear side consists of a shaped part of plastic, glass or ceramic.

DE 20 220 444 U1 discloses a photovoltaic module with at least one front-side, outer covering layer of glass or an impact-resistant, UV-stable, weather-proof, transparent plastic with low water-vapor permeability, facing the energy source, at least one layer of adhesive plastic, which is located between the covering layer and a rear-side layer and embedded in which is or are at least one or a number of solar cells, which are electrically connected to one another, and at least one rear-side outer layer of glass or a weather-proof plastic with low water-vapor permeability, facing away from the energy source.

On account of their structure, the vehicle surface components of the cited prior art have a high weight and/or require a complex production process.

The invention is based on the object of providing a vehicle surface component that has a low weight and high stability.

This object is achieved by the features of patent claim 1. Advantageous refinements are specified in the subclaims.

Producing the carrying layer of a solar cell arrangement in the way according to the invention as a composite lightweight construction allows vehicle surface components with great intrinsic stiffness and low weight to be provided, suitable for various uses on vehicles. An intrinsically stiff and light composite lightweight component forms a particularly suitable carrier structure for solar cell arrangements, whereby stiffening measures for the solar cell arrangements can be omitted or are only required to a reduced extent. This dispenses entirely with the inner support provided by a solid carrier plate of glass that has until now been customary in the case of glass covers of vehicle roofs provided with solar cells. The outside outer layer of a vehicle surface component can also be made much thinner and lighter than before as a result of the high load-bearing capacity of the composite lightweight component, which forms the carrying layer on the inner side of the solar cell arrangement. Altogether, the vehicle surface component according to the invention becomes much lighter with the same or even increased stability, without any increase in the overall thickness of the component. By reducing the component and simplifying the production process, a cost reduction can be additionally achieved thereby.

For the purposes of the invention, “composite lightweight construction” or “composite lightweight component” is understood as meaning a multilayer component formed from at least two, preferably at least three, interconnected layers of different materials from which the carrying layer is formed, at least one layer consisting of a material and/or an arrangement with a relatively great volume and relatively low weight.

The carrying layer may be formed “monolithically” as a composite lightweight component, for example from polyurethane with an embedded fiber reinforcement. Coming into consideration as fiber reinforcement are glass fibers, carbon fibers, natural fibers, such as for example sisal, hemp or flax, or synthetic fibers, such as for example aramid, either in the form of loose chopped fibers as an admixture for the polyurethane in a spraying, casting, foaming or injecting process in an open or closed mold, in the latter case also combined with a pressing operation following a spraying, casting or injecting operation, or the fiber reinforcement is used in the form of mats, woven or knitted fabrics or meshes for a layered structure, alternating as layers respectively with a layer of plastic, in particular a polyurethane layer.

An example of a “monolithic” structure of the carrying layer is a carrying layer produced from Baydur® of Bayer MaterialScience AG (Baydur® is a registered trademark of Bayer AG) by the PUR Composite Spray Molding process (CSM process), chopped glass fibers being fed in a metered manner from the outside to the sprayed jet of polyurethane introduced into an open mold. This is followed by the molding of the shaped part by foaming in the closed mold. The random distribution of the glass fibers imparts a high mechanical strength in all loading directions to a carrying layer produced in this way, and consequently provides optimum support for the solar assembly and high stiffness of the vehicle surface component with relatively low weight.

An example of a structure of a carrying layer with alternating layers as a composite lightweight component is created by another variant of the PUR Composite Spray Molding process (CSM process) for processing Multitec® (Multitec® is a registered trademark of Bayer AG). Here, chopped long fibers are likewise introduced together with the polyurethane mixture into an open mold. The polyurethane mixture is in this case applied in multiple layers—in a compact or foamed form and optionally reinforced or un-reinforced—and cures in an open mold at room temperature.

In a further variant of the PUR Composite Spray Molding process (CSM process), natural fiber mats, of hemp, sisal, flax, coconut or the like, sprayed with a special polyurethane spraying system, are pressed into thin-walled, extremely light shaped parts for a composite lightweight component as a carrying layer by using Baypreg® F (Baypreg® is a registered trademark of Bayer AG).

A further variant of a composite lightweight construction for the carrying layer is formed by a sandwich structure, in which a specifically lighter layer of a plastic, a foam and/or a honeycomb structure is arranged between a lower and an upper outer layer of plastic or lightweight metal.

An example of a sandwich structure of the carrying layer as a composite lightweight component with a layer of plastic arranged between a lower and an upper outer layer is the material Hylite® or Alubond® (both registered trademarks of ALCAN Singen GmbH) with outer layers of aluminum and a layer of polypropylene (PP). The polypropylene layer may also be substituted by another suitable light plastic with high strength, such as polyamide.

A further example of a sandwich structure of the carrying layer as a composite lightweight component is a honeycomb structure of paper or paperboard, metal or plastic, also known by the name “honeycomb structure”, in which a honeycomb structure formed between two closed outer layers by walls arranged perpendicularly in relation to the outer layers encloses cavities (“open honeycomb structure”). The vertical walls are permanently adhesively bonded in their regions adjacent to the outer layers, for example by a plastic sprayed on before assembly (as shown in DE 100 33 232 C2 for a vehicle roof part without a solar unit). An example of a lightweight metal honeycomb structure of this type is the material Alucore® (registered trademark of ALCAN Singen GmbH). Instead of the cavities, a solid core material, for example a plastic or a plastic foam or metal foam, may be arranged between the walls of the honeycomb structure (“closed honeycomb structure”). An open or closed honeycomb structure may finally also be joined together with the Baypreg® F described above, by spraying and pressing, to form a carrying layer.

In principle, the solar cell arrangement may be connected to the plastic composite component to form a vehicle surface component when said plastic composite component is being produced or be subsequently applied, and in particular adhesively attached, to a prefabricated composite lightweight component. The joint operation of producing the composite lightweight component and connecting it to the solar cell arrangement is preferably performed, for example, by thermal forming and lamination in a single process step. The solar cell arrangement may optionally also be prefabricated with at least one carrier layer and with films of hotmelt adhesive to form a precomposite or prelaminate.

The solar cell arrangement may be applied to a planar or curved surface of the composite lightweight component or be integrated in it during production.

The solar cell arrangement may cover the entire composite lightweight component. It may, however, also leave peripheral regions of it free. In this case, the solar cell arrangement may protrude upwardly, with an upper outer layer of the vehicle surface component perpendicular to the surface of the composite lightweight component. On the other hand, the solar cell arrangement may also be fitted or integrated in a depression provided on the upper side of the composite lightweight component, so that it is arranged flush with raised peripheral regions of the composite lightweight component.

Above the solar cell arrangement, the vehicle surface component has a transparent covering. This is formed by a covering film or a thin glass plate. As a transparent thermoformed sheet part, the covering film can cover the entire vehicle surface component.

In a preferred refinement, it is provided that, in the case of a solar cell arrangement that is particularly arranged on the composite lightweight component in a recessed and flush manner, sealing is provided in a gap between the periphery of the solar cell arrangement and the adjacent region of the composite lightweight component,
a seal being adhesively attached to the composite lightweight component, or
a seal being adhesively attached to the periphery of the solar cell arrangement, or
a sealing cord being inserted in the gap, or
a sealing compound adapted to the form of the gap filling the gap, or
a seal being inserted in the gap and reaching over the adjacent components with two sealing lips.

Vehicle surface components according to the invention may be used, for example, for roof modules without opening systems, roof modules with opening systems (sliding roofs, lifting roofs, sliding/lifting roofs, externally guided sliding roofs, panoramic roofs, spoiler roofs, lamella roofs, retrofitted roofs and the like), for covers of roof opening systems, for roof shells of roofs for hardtop convertibles (also known as “Retractable Hardtops”=“RHTs”), for draft deflector strips, for spoilers, for rear lids, engine hoods, doors or fenders as well as for A, B, C and D pillars.

The invention is explained in more detail below on the basis of exemplary embodiments of vehicle surface components according to the invention with reference to the drawing, in which:

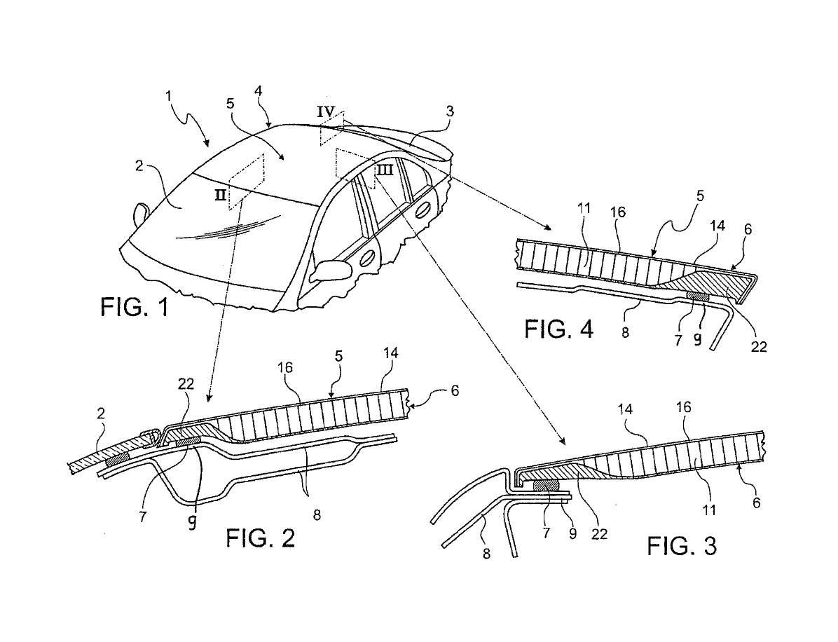

FIG. 1 shows a perspective plan view of a vehicle with a vehicle surface component according to the invention in the form of a roof module;

FIG. 2 shows a cross-sectional view II according to FIG. 1, in the vertical central longitudinal plane of the vehicle, of a front portion of the roof module;

FIG. 3 shows a cross-sectional view III according to FIG. 1, in a vertical transverse plane of the vehicle, of a side portion of the roof module;

FIG. 4 shows a cross-sectional view IV according to FIG. 1, in the vertical central longitudinal plane of the vehicle, of a rear portion of the roof module;

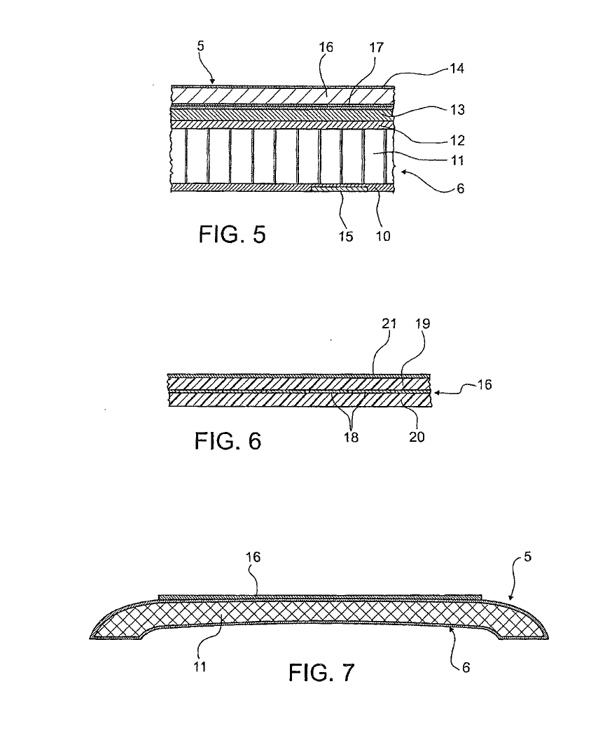

FIG. 5 shows a sectional view of a detail of a plastic composite component of a vehicle surface component according to the invention, which is produced in the manner of a composite lightweight construction by the CSM process and is provided with a solar cell arrangement attached to it;

FIG. 6 shows a sectional view of the solar cell arrangement of the vehicle surface component;

FIG. 7 shows a cross-sectional view of a roof module with a solar cell arrangement which is adhesively attached to a composite lightweight component and is kept at a distance from the periphery of the roof module;

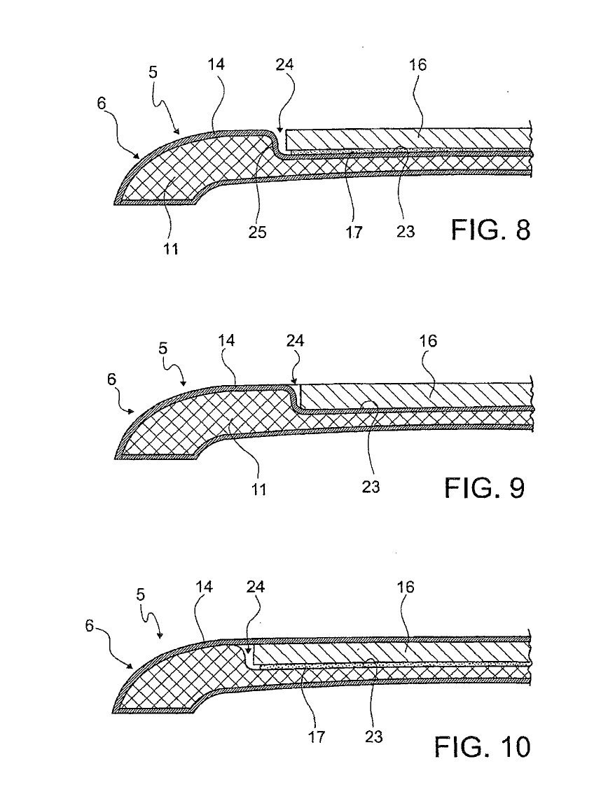

FIG. 8 shows a cross-sectional view of a further exemplary embodiment of a roof module, in which the solar cell arrangement is adhesively fitted in a depression on the upper side;

FIG. 9 shows a cross-sectional view of a further exemplary embodiment of a roof module;

FIG. 10 shows a cross-sectional view of a further exemplary embodiment of a roof module;

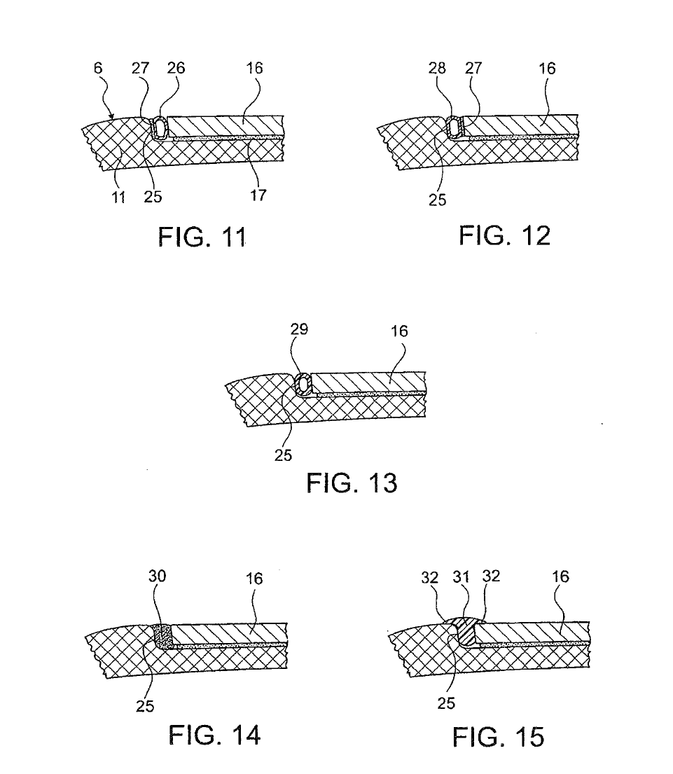

FIG. 11 shows a cross-sectional view of a seal in a gap between a periphery of the solar cell arrangement accommodated in a depression of the composite lightweight component and a flank of the plastic composite component;

FIG. 12 shows a cross-sectional view of a further exemplary embodiment of a seal according to the arrangement of FIG. 11;

FIG. 13 shows a cross-sectional view of a further exemplary embodiment of a seal according to the arrangement of FIG. 11;

FIG. 14 shows a cross-sectional view of a further exemplary embodiment of a seal according to the arrangement of FIG. 11;

FIG. 15 shows a cross-sectional view of a further exemplary embodiment of a seal according to the arrangement of FIG. 11;

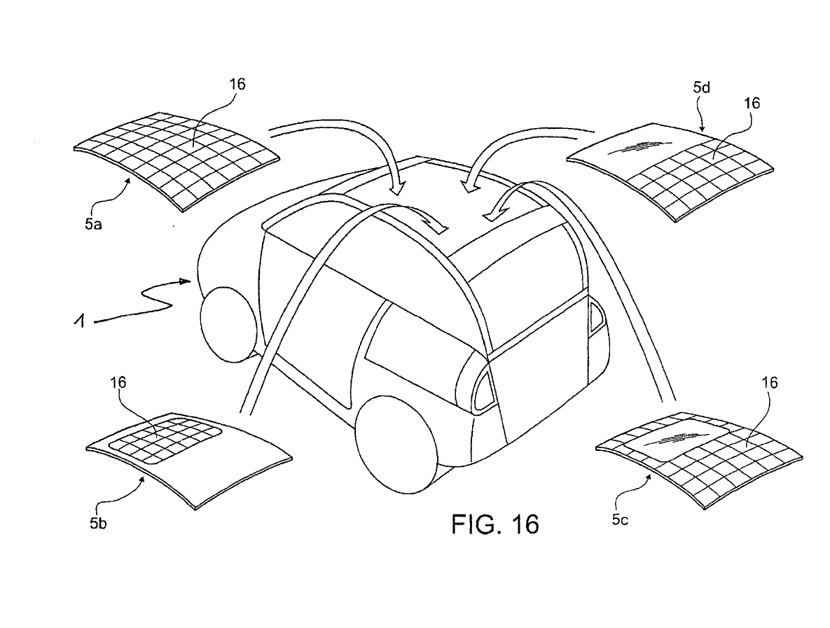

FIG. 16 shows a perspective plan view of a vehicle to which roof modules with various solar cell arrangements can be attached;

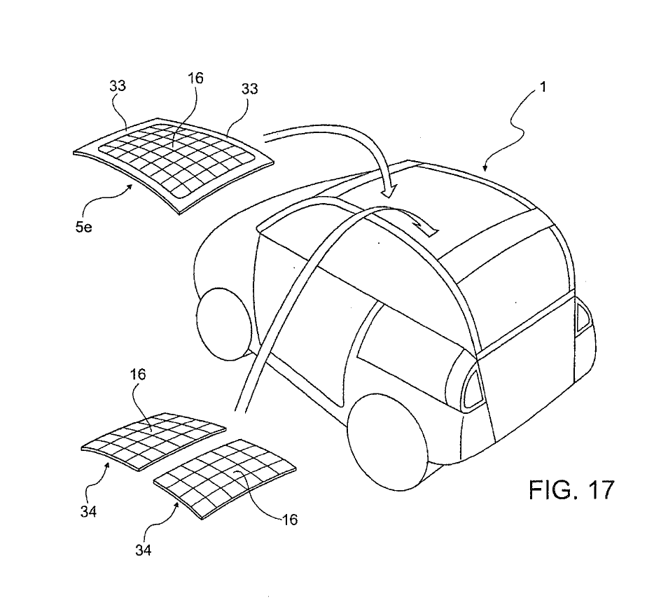

FIG. 17 shows a perspective plan view of a vehicle with further exemplary embodiments of roof modules according to the invention;

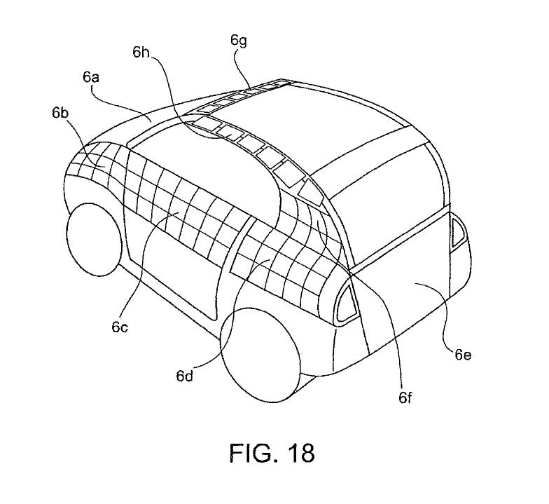

FIG. 18 shows a perspective plan view of a vehicle with further exemplary embodiments of vehicle surface components according to the invention;

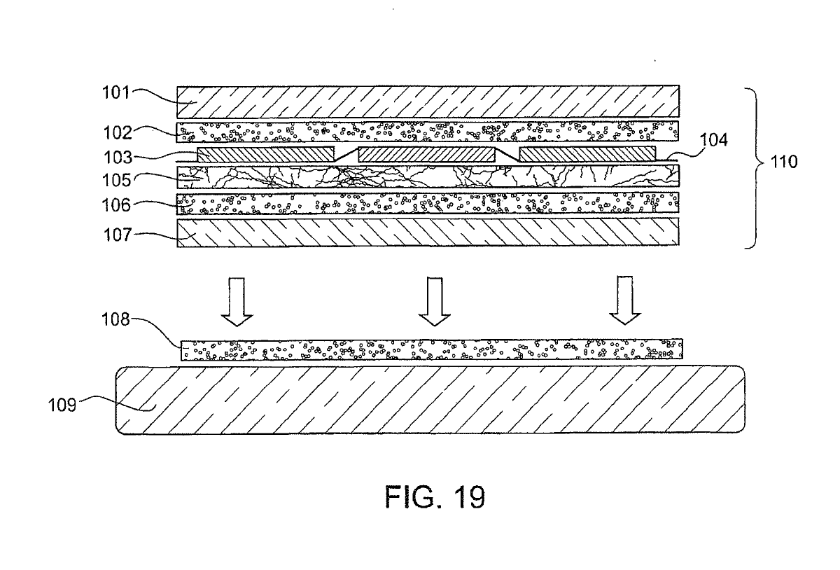

FIG. 19 shows a schematic sectional representation of a composite lightweight component with a solar cell arrangement as a laminar structure;

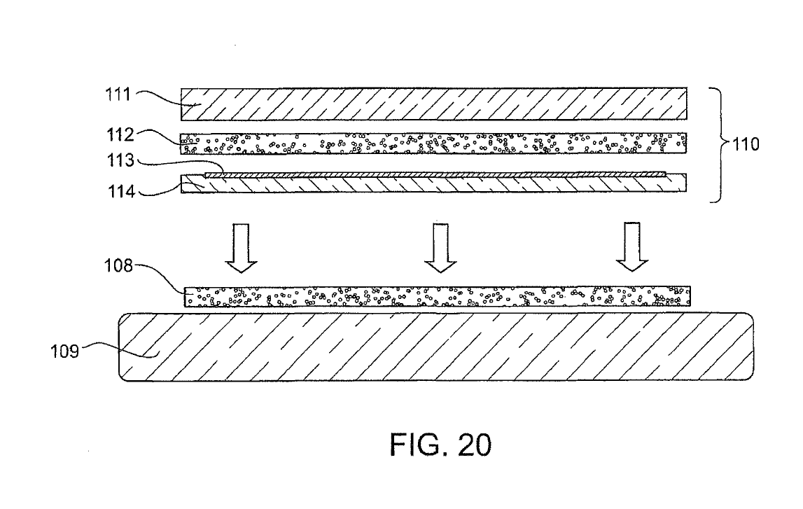

FIG. 20 shows a further variant of a composite lightweight component with a solar cell arrangement as a laminar structure;

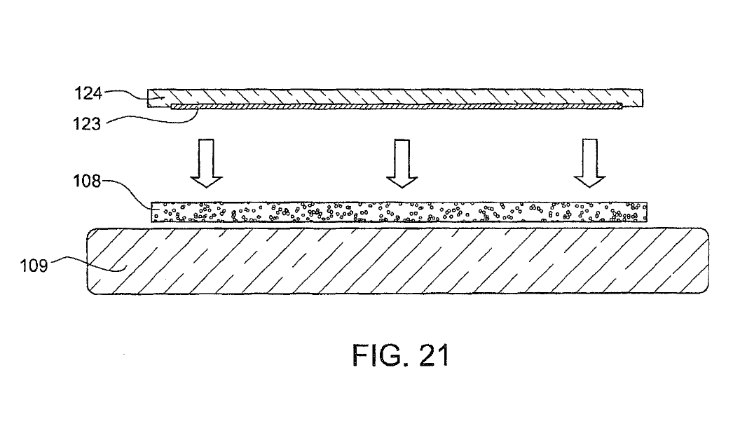

FIG. 21 shows a further variant of a composite lightweight component with a solar cell arrangement as a laminar structure;

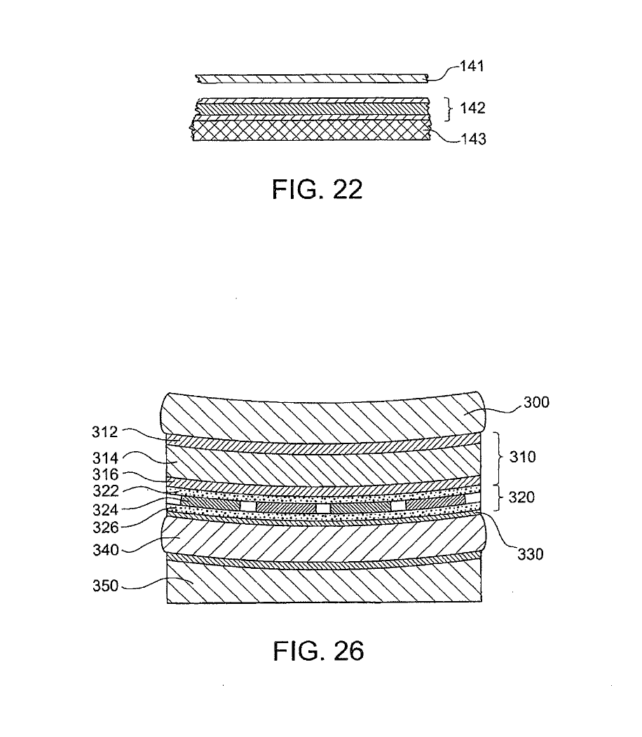

FIG. 22 shows a further variant of a composite lightweight component with a solar cell arrangement as a laminar structure;

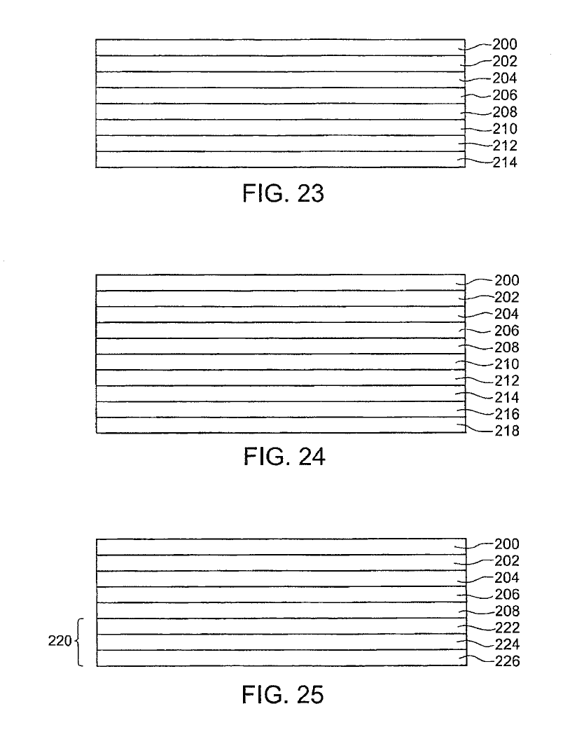

FIG. 23 shows a highly schematized structure of a composite lightweight component with a solar cell arrangement as a laminar structure;

FIG. 24 shows a highly schematized structure of a further composite lightweight component with a solar cell arrangement as a laminar structure;

FIG. 25 shows a highly schematized structure of a further composite lightweight component with a solar cell arrangement as a laminar structure;

FIG. 26 shows a variant of a composite lightweight component with a solar cell arrangement curved in a mold as a laminar structure.

A vehicle 1, such as for example a passenger car (see FIG. 1), has a front windshield 2 and a rear windshield 3 as well as a vehicle roof 4 with a roof module 5, which extends from the front windshield 2 to the rear windshield 3. The roof module 5 as well as other parts such as the fenders, engine hood or baggage-compartment lid of the vehicle may be formed by a vehicle surface component 6 according to the invention, a detail of which is shown enlarged in FIG. 5.

The roof module 5, as the first exemplary embodiment of a vehicle surface component 6 according to the invention, is fastened to a roof frame 8 or to flange regions 9 of the roof frame 8 by means of a bead of adhesive 7, in particular running around the periphery.

The roof module 5 or the vehicle surface component 6 is produced in the manner of a lightweight construction with a composite lightweight component in a sandwich-like layered structure (see FIG. 5 in particular) and contains, from the inside outward, a first inner carrying layer 10, as the lower outer layer, a core layer or spacer layer 11, formed as a honeycomb structure, a second outer carrying layer 12, as the upper outer layer, and a decoupling layer 13. This structure is produced by the CSM process. An outer skin 14 completes the layered structure as an outer layer on the outside.

The carrying layers 10 and 12 preferably consist of polyurethane (PU) with a weight per unit area of approximately 300 g/m², which is optionally and preferably reinforced respectively by means of a glass fiber mat with a weight per unit area of approximately 225 g/m².

The core layer or spacer layer 11 preferably consists of a honeycomb structure and in particular of a paper honeycomb, for example with a thickness of approximately 13 mm, the corrugation and sheet of the honeycomb structure having a weight per unit area of in each case approximately 115 g/m².

The decoupling layer 13 preferably has a thickness of approximately 2 to 2.5 mm. It serves the purpose of effectively preventing a visible impression of the honeycomb structure appearing on the outer skin 14 that could otherwise occur during compression in a mold if the decoupling layer 13 were not provided.

The layered structure, comprising the core layer or spacer layer 11 and the two neighboring carrying layers 10 and 12, is produced by means of the CSM process (composite spray molding), which is known from Hennecke GmbH, D-53754 Sankt Augustin, in a mold (CSM mold). The layered structure is also represented in a similar form in DE 100 33 232 C2. With very low weight, the strength of the layered structure is achieved in particular by the plastic, preferably polyurethane (PU), penetrating into the region of the vertical walls of the honeycombs and bonding with them.

The outer layer or outer skin 14 of the composite lightweight component or of the vehicle surface component 6 is preferably created directly in the CSM mold by spraying in a layer thickness of 0.03 to 0.06 mm (S&R) or in a layer thickness of 0.3 to 0.6 mm (Panadur®) by the IMC process (in-mold coating).

On the inner side of the vehicle surface component 6 or the roof module 5, inserts 15 of metal, which serve for fastening neighboring components, such as for example sun visors or grab handles, may be embedded, for example, in the first carrying layer 10, serving as the lower outer layer.

This basic structure may be modified and, for example, supplemented by at least one additional layer, such as for example a shatterproof layer (not represented) between the first carrying layer 10 and the core layer 11 and possibly between the core layer or spacer layer 11 and the second carrying layer 12.

A solar cell arrangement 16, which is also referred to as a solar pack or solar module, is attached by means of an adhesive layer 17 on the outer upper side of the plastic composite component, which is formed by the layers 10, 11 and 12. The solar cell arrangement 16 contains (see FIG. 6) a layer of solar cells 18, which are accommodated between an upper EVA film 19 and a lower EVA film 20 (EVA: ethylene-vinyl acetate). The solar cells 18 have a thickness of, for example, approximately 0.2 mm and the EVA films 19 and 20 are approximately 0.46 mm thick. The upper side of the solar cell arrangement 16 forms, for example, a transparent film 21, which consists, for example, of ETFE (ethylene tetrafluoroethylene) and has a thickness of, for example, 0.15 mm, or a glass sheet or thin glass sheet in a thickness of less than 3.0 mm, preferably of less than 1.0 mm.

In the case of the vehicle surface component 6 forming the roof module 5 according to FIGS. 1 to 4, consequently the carrying layer, formed as a composite lightweight component and consisting of the layers 10, 11 and 12, is first produced by the CSM process. Subsequently or in the same process step, the solar cell arrangement 16 is adhesively attached over the full surface area up to the outer peripheries of the vehicle surface component 6 or the roof module 5, or at the same time laminated on together with the carrying layer. Depending on the type and thickness of the film or sheet 21, the composite comprising the solar cell arrangement 16 and the carrying layer 10, 11, 12 is optionally also additionally provided on the outer side of the later vehicle surface component 6 or the roof module 5 with a wear- and scratch-resistant outer skin 14 (see also FIG. 10).

In the peripheral regions, the vehicle surface component 6 of the roof module 5 may be compressed to a greater degree in the mold, there being formed instead of the core layer 11a layer 22, which increases the stability of the roof module 5 and is preferably produced by spraying polyurethane with injected fiber material in the LFI-PUR process (LFI=long fiber injection molding). After the roof module 5 has been fitted, these peripheral regions or layers 22 of increased strength are located on the supporting surfaces or the flange regions 9 of the roof frame 8, in the region of the beads of adhesive 7.

In the case of a modified embodiment of the roof module 5 (see FIG. 7), the prefabricated solar cell arrangement 16 has been applied, and in particular adhesively attached, to the composite lightweight component of the vehicle surface component 6, which has likewise been prefabricated with the honeycomb-like core layer 11, the solar cell arrangement 16 not extending up to the lateral peripheries of the vehicle surface component 6 but being arranged at a distance from them. In an alternative way of performing the process or production, the solar cell arrangement 16 may be placed into an assigned depression in a back-filling mold of the CSM process and foamed directly onto or into the surface of the composite lightweight component when said component is being produced.

FIG. 8 shows an embodiment in which the solar cell arrangement 16 is subsequently adhesively fitted into a depression 23 on the upper side of the vehicle surface component 6 by means of an adhesive layer 17. The outer skin 14 may be produced by the IMC process (in-mold coating), for example in a black color, or it may be subsequently painted in the color of the car. A peripheral gap 24 between the periphery of the solar cell arrangement 16 and a flank 25 of the composite lightweight component at the transition to the depression 23 thereof is preferably covered or sealed by a seal, as represented in FIGS. 11 to 15.

In the case of the embodiment of FIG. 9, the solar cell arrangement 16 is arranged on the composite lightweight component and fastened thereto in an integrated production process when said component is being produced. This is performed by the solar cell arrangement 16 being placed into a back-filling mold of the CSM process and attached to the composite lightweight component by being integrated in the depression 23 on the upper side during the subsequent CSM process. The peripheral gap 24 between the periphery of the solar cell arrangement 16 and the flank 25 of the plastic composite component is filled by plastic, so that no additional seal is required, whereby the appearance is improved because there is no gap, joint or seal. Since a separate adhesive bonding operation is not required for attaching the solar cell arrangement 16, the production costs are reduced.

In the case of the roof module 5 according to the exemplary embodiment of FIG. 10, a transparent film is brought into the required form to act as an outer skin 14 by thermoforming and is subsequently placed into a CSM mold. The solar cell arrangement 16, which may be formed without the outer film 21, is applied to the inner side of the transparent film or outer skin 14, which may replace the outer film 21. The composite lightweight component is produced by the CSM process, it being possible for parts of the composite lightweight component, and in particular carrying peripheral portions, also to be produced with LFI or PU (see layer 22 in FIGS. 2 to 4). The continuous thermoformed film or outer skin 14 provides a particularly good appearance at the transition or the peripheral gap 24 between the solar cell arrangement 16 and the composite lightweight component or the flank 25 thereof at the depression 23.

FIGS. 11 to 15 show types of sealing for the peripheral gap 24, as it occurs, for example, in the exemplary embodiments according to FIGS. 8 to 10.

A seal 26 (see FIG. 11), for example an elastic hollow-chamber sealing profile of rubber, as known in principle from sliding roofs for example, is fastened by means of an adhesive 27 to the composite lightweight component or the flank 25 thereof, lies tight against the periphery of the solar cell arrangement 16 and does not protrude upward out of the peripheral gap 24.

At a comparable peripheral gap 24 (see FIG. 12), the seal 28 is adhesively attached to the periphery of the solar cell arrangement 16 by means of the adhesive 27 and lies tight against the composite lightweight component or the flank 25 thereof.

FIG. 13 shows a peripheral gap 24, which is sealed by means of a seal in the form of an elastic sealing cord 29, which is inserted in the peripheral gap 24 and fixed to the neighboring components on account of its adhesive surface. In addition, the sealing cord 29 may be secured by an adhesive bond, which only has to have low retaining forces.

The seal of the peripheral gap 24 according to FIG. 14 is formed by a molding or sealing compound 30, which fills the peripheral gap 24 in the manner of a silicone jointing filler.

The sealing of the peripheral gap 24 according to FIG. 15 is performed by means of a sealing strip 31, which is inserted into the peripheral gap 24 and has on the outside two sealing lips 32, which reach over the solar cell arrangement 16 or the composite lightweight component on both sides of the peripheral gap 24 and consequently seal it reliably.

These seals, given by way of example, may be used at any desired gaps at the periphery of solar cell arrangements 16 on various vehicle surface components 6.

FIG. 16 shows by way of example a vehicle 1 to which various roof modules 5 can be attached. Such a roof module 5a, produced in the manner of a composite lightweight construction, may be covered with solar cells 16 over the full surface area. Alternatively, peripheral regions on a roof module may remain free of solar cells 16. Furthermore, a cover 5b, produced in the manner of a composite lightweight construction, of the vehicle roof may be partially or completely covered with solar cells 16. A roof module 5c, produced in the manner of a composite lightweight construction, with an opening system may be covered with solar cells 16 on its rigid immovable regions. A roof module 5d, produced in the manner of a composite lightweight construction, may have a panoramic glass roof on its front portion and be covered with solar cells 16 in its rear portion.

Furthermore (see FIG. 17), a roof module 5e, produced in the manner of a composite lightweight construction and having peripheral regions 33 that are free of solar cells 16, may be attached to the vehicle roof 4 and the outer skin 14 may be formed in a black color at the free peripheral regions 33, or the peripheral regions 33 are painted in the color of the car. The vehicle 1 may be a convertible with an adjustable single- or multi-shell hardtop roof (RHT=Retractable Hardtop) and each roof shell 34, produced in the manner of a composite lightweight construction, may be provided with a solar cell arrangement 16.

According to further exemplary embodiments (see FIG. 18), further vehicle surface components, produced in the manner of a composite lightweight construction, such as for example the engine hood 6a, the fenders 6b, the door linings 6c, the outer skin panels 6d, the baggage-compartment lids or rear lids 6e, with substantially vertical or horizontal surfaces, the C pillars 6f, a cowl 6g or the roof frame 6h, may be provided with solar cell arrangements 16.

FIGS. 19 to 21 schematically show three embodiments of a movable or immovable vehicle surface component, it also being possible for regions of the body other than the vehicle roof to be equipped with them. The vehicle surface component according to FIG. 19 consists, from top to bottom or, when in position for use, from the outside inward:
an outer layer 101, preferably formed by an outer weather-resistant, UV-stable and scratch-resistant outer film; this may consist of polycarbonate (PC), polymethylmethacrylate (PMMA), polyethylene terephthalate (PET), ethylene tetrafluoroethylene (ETFE), perfluoroethylene-propylene copolymer (FEP) or some other transparent plastic or thin glass,
a transparent layer of hotmelt adhesive 102 comprising a hotmelt adhesive with good tack, such as ethylene vinyl acetate (EVA), thermoplastic polyurethane (TPU), polyvinyl butyral (PVB) or an ionomer,
at least one solar cell 103, a number of solar cells are interconnected by cell connectors 104; conventional crystalline or polycrystalline solar cells, produced by the pulling or casting process, may be used as solar cells 103,
stranded conductors are preferably used as cell connectors 104 because of the thermal expansion,
a separating layer 105 of a fibrous material, such as glass mat, to separate the colored or tinted hotmelt adhesive 106 below the solar cells 103 from the transparent hotmelt adhesive 102 above the solar cells 103 from one another,
a preferably tinted or colored layer of hotmelt adhesive 106, comprising a hotmelt adhesive with good tack, such as ethylene vinyl acetate (EVA), thermoplastic polyurethane (TPU), polyvinyl butyral (PVB) or an ionomer,
optionally a rear film of PC, PMMA, PET, ETFE, PVF (polyvinyl fluoride), PVDF (polyvinylidene fluoride); this may also be omitted, and
a carrier plate comprising a composite lightweight component, such as Hylite®, Alubond®, CSM composites (honeycomb, foam) or Alucore®.

In the case of the exemplary embodiment according to FIGS. 20 and 21, thin-film solar cells are used as solar cells 113 or 123, based on the thin-film technologies such as copper-indium diselenide (CIS) or copper-indium sulfide (CIS), copper-indium-gallium diselenide (CIGS), micro-amorphous silicon (a-Si:H/pc-Si:H), amorphous silicon (a-Si:H) or cadmium telluride (CdTe/CdS).

In the case of the exemplary embodiment according to FIG. 20, the solar cells 113 are arranged below the outer layer 111 and the layer of hotmelt adhesive 112 (which correspond in their structure to the outer layer 101 and the layer of hotmelt adhesive 102 from FIG. 19) on a carrier layer 114, which serves as a substrate and is preferably formed as a thin glass layer (glass plate). The solar cell assembly described above is connected to the carrying layer 109 by means of a layer of hotmelt adhesive 108. The layers 108 and 109 correspond in their structure to the example according to FIG. 19.

In the case of the exemplary embodiment according to FIG. 21, the solar cells 123 are arranged below the carrier layer 124, which serves as a superstrate and is preferably formed as a thin glass layer. The solar cell assembly described above is connected to the carrying layer 109 by means of a layer of hotmelt adhesive 108. The layers 108 and 109 correspond in their structure to the example according to FIG. 19.

The laminating of the solar cell assembly to the carrying layer 109 is preferably carried out at a temperature of approximately 110-150° C. and a pressure of 1 to 15 bar. Used as the laminating process are: lamination in a vacuum laminator or the vacuum-bag process in a circulating air oven or an autoclave.

The solar cell assembly represented in FIG. 19, comprising the layers 101, 102, 103, 104, 105, 106 and 107, is in one embodiment also produced as a precomposite or prelaminate 110 and is then connected to the carrying layer 109, formed as a composite lightweight component. In a minimal variant, the precomposite 110 may also consist only of the layers 101, 102, 103 and 104 and be connected to the carrying layer 109 by means of the layer of hotmelt adhesive 108.

In the case of the embodiment represented in FIG. 20, the layers 111, 112, 113 and 114 may also optionally be produced as a precomposite or prelaminate 110 and then be connected to the carrying layer 109, formed as a composite lightweight component, by means of the layer of hotmelt adhesive 108. If, in the case of the exemplary embodiment according to FIG. 21, under the layers 124 and 123 there is also optionally arranged a layer of hotmelt adhesive and a lower covering layer or barrier layer (both not shown), which forms a corrosion protection for the solar cell layer 113, this laminar structure may also be produced as a precomposite or prelaminate and then be connected to the carrying layer 109, formed as a composite lightweight component, by means of the layer of hotmelt adhesive 108.

In the case of the embodiment of a vehicle surface component according to FIG. 22, a layer of plastic 141 (for example of polycarbonate or of PMMA), serving as an outer layer facing the outside, is made relatively thin, so that an additional carrier layer 143 has to be used for stabilization. This layer is arranged on the underside of the arrangement, so that the solar cell assembly 142 is arranged between the polycarbonate layer 141 and the carrier layer 143. A PU sandwich component produced by the so-called compound spray molding process (CSM process) may be used as the carrier layer 143.

The PU sandwich component consists of a honeycomb structure or a foam core (for example polystyrene (PS) or polyurethane (PU)), which is compressed between two glass fiber mats sprayed with polyurethane. Also in the case of this exemplary embodiment, the solar cell assembly 142 and the layer of plastic 141 may be produced as a precomposite or prelaminate and then connected to the carrying layer 143, formed as a composite lightweight component.

In FIGS. 23 to 25, further advantageous embodiments of a composite lightweight component are represented in a highly schematized form. The schematized representation shows all the layers as having the same thickness. In reality, the layers have layer thickness that differ considerably from one another, as already specified further above in connection with FIG. 5.

The composite lightweight component represented in FIG. 23 consists, from the outside inward, or in the figure from top to bottom, of the following layers:
an outer layer 200 of thin glass or a weather-proof, scratch- and wear-resistant plastic, such as polycarbonate (PC), polymethylmethacrylate (PMMA), polyethylene terephthalate (PET), ethylene tetrafluoroethylene (ETFE) or perfluoroethylene-propylene copolymer (FEP),
a connecting layer 202 of a hotmelt adhesive with good tack, such as ethylene vinyl acetate (EVA), thermoplastic polyurethane (TPU), polyvinyl butyral (PVB) or an ionomer,
a solar cell arrangement 204,
a separating layer 206 of a fibrous material, such as a glass mat, to separate the colored or tinted hotmelt adhesive below the solar cells from the transparent hotmelt adhesive above the solar cells in the flowing state during lamination distinctly from one another,
a connecting layer 208 of a hotmelt adhesive with good tack, such as EVA, TPU, PVB or an ionomer,
a metal layer 210, for example comprising a thin aluminum sheet,
a layer of plastic 212 comprising a strong but lightweight plastic, such as polypropylene (PP) or polyamide (PA), and
a metal layer 214, for example comprising a thin aluminum sheet.

The lower three layers 210, 212 and 214 form a sandwich structure, as known, for example, under the trade name Hylite® (registered trademark of ALCAN Singen GmbH).

The composite lightweight component represented in FIG. 24 consists, from the outside inward, or in the figure from top to bottom, of the following layers:
an outer layer 200 of thin glass or a weather-proof, scratch- and wear-resistant plastic, such as PET, PC, PMMA, ETFE or FEP,
a connecting layer 202 of a plastic or hotmelt adhesive with good tack, such as EVA, TPU, PVB or an ionomer,
a solar cell arrangement 204,
a separating layer 206 of a fibrous material, such as a glass mat, to separate the colored or tinted hotmelt adhesive below the solar cells from the transparent hotmelt adhesive above the solar cells in the flowing state during lamination distinctly from one another,
a connecting layer 208 of a plastic or hotmelt adhesive with good tack, such as EVA, TPU, PVB or an ionomer,
a metal layer 210, for example comprising a thin aluminum sheet,
a layer of plastic 212 comprising a strong but lightweight plastic, such as PP or PA,
a metal layer 214, for example comprising a thin aluminum sheet,
a layer of plastic 216 comprising a strong but lightweight plastic, such as PP or PA, and
a metal layer 218, for example comprising a thin aluminum sheet.

The lower five layers 210, 212, 214, 216 and 218 form a double sandwich structure that has an extremely good load-bearing capacity.

The composite lightweight component represented in FIG. 25 consists, from the outside inward, or in the figure from top to bottom, of the following layers:
an outer layer 200 of thin glass or a weather-proof, scratch- and wear-resistant plastic, such as PET, PC, PMMA, ETFE or FEP,
a connecting layer 202 of a plastic or hotmelt adhesive with good tack, such as EVA, TPU, PVB or an ionomer,
a solar cell arrangement 204,
a separating layer 206 of a fibrous material, such as a glass mat, to separate the colored or tinted hotmelt adhesive below the solar cells from the transparent hotmelt adhesive above the solar cells in the flowing state during lamination distinctly from one another,
a connecting layer 208 of a plastic or hotmelt adhesive with good tack, such as EVA, TPU, PVB or an ionomer,
an upper outer layer 222, which consists of metal, for example comprises a thin aluminum sheet, or a fiber/plastic composite, such as glass fiber, which is embedded in PU,
a honeycomb layer 224, with a honeycomb structure of paper, paperboard, metal or plastic, it being possible for the honeycomb structure to enclose cavities, or
instead of the honeycomb layer 224, a foam core 224 of polystyrene (PS) or polyurethane (PU) or metal, and
a lower outer layer 226, which consists of metal, for example comprises a thin aluminum sheet, or a fiber/plastic composite, such as glass fiber, which is embedded in PU.

The three lower layers 222, 224 and 226 form a sandwich structure 220, which has very great stability with extremely low weight.

The carrying layer of the vehicle surface component, which in FIG. 23 is formed by the sandwich structure of the lower three layers 210, 212 and 214, in FIG. 24 is formed by the double sandwich structure of the lower five layers 210, 212, 214, 216 and 218 and in FIG. 25 is formed by the sandwich structure 220, may be preformed as a rigid component and subsequently connected to the other component parts by lamination.

However, it is particularly advantageous if the composite comprising the carrying layer, the solar cells and preferably also the outer layer is created in one process step by simultaneous thermal forming and lamination.

The peripheral termination of the composite lightweight component may be performed in the way described below. In the peripheral region of the aluminum-polypropylene(PP)-aluminum plate (corresponding to the lower three layers 210, 212 and 214 in FIG. 4), the PP core could be removed in a suitable way (for example by milling), in order that a correspondingly shaped profile seal can be accommodated. A polyurethane (PU) encapsulation of the edge of the composite lightweight component may also be anchored in a milled groove. Similarly, before the lamination, the edges could be bordered, in order that the edges are sealed. Bending over of the transparent film of plastic during the lamination/thermal forming process and subsequent adhesive bonding to the PP layer may also be carried out.

During the thermoforming operation, additional stiffening curvatures or stiffening elements could be introduced, serving for stiffening the component or the depression for the solar cell arrangement.

The disadvantage of the procedure based on two independent production operations is eliminated by using suitable materials to allow the two operations to be performed in one process. This means that the three-dimensional shaping and the lamination to form a solar assembly are performed in just one process step, as represented by an example shown in FIG. 26.

In FIG. 26, a mold carrier 350 is provided, mounted on which is a lower mold 340. In the upward direction, the arrangement shown is delimited by an upper mold 300. In the simplest case, the lower mold 340 and the upper mold 300 may be respectively formed by a sheet preformed in a way corresponding to the desired curvature of the vehicle surface component 6. The following layers of a vehicle surface component, formed as a composite lightweight component, are arranged between the lower mold 340 and the upper mold 300, from the bottom upward, the lowermost layer corresponding to the layer that is later the outer layer on account of the arrangement deviating from the later position for use:
an outer layer 330
a layer of hotmelt adhesive 326
a solar cell layer 324
a layer of hotmelt adhesive 322
an outer layer 316
a spacer layer 314
an outer layer 312

The layers of hotmelt adhesive 322 and 326 form with the solar cell layer 324 a solar cell module 320, which may be prefabricated.

The outer layers 316 and 312 form with the spacer layer 314, arranged between them, a composite plate 310.

The material of the individual layers corresponds to that of the exemplary embodiments described above. The composite plate 310 is stable and lightweight, preferably formed as a sandwich lightweight component. It forms the carrying layer in the sense of the main claim.

The outside outer layer 330 consists of a lightweight, wear-resistant and scratch-resistant material, such as thin glass or plastic (for example corresponding to the component 124 in FIG. 21).

Conventional monocrystalline or polycrystalline solar cells may be used as solar cells 324, produced by the pulling or casting process, or thin-film solar cells based on the thin-film technologies such as copper-indium diselenide or copper-indium sulfide (CIS), copper-indium-gallium diselenide (CIGS), micro-amorphous silicon (a-Si:H/μc-Si:H), amorphous silicon (a-Si:H) or cadmium telluride (CdTe/CdS).

With particular preference, all the layers are placed together on the lower mold 340 and, by lowering the upper mold 300 and a thermal binding process, are connected to one another and at the same time brought into the desired form in one operation.

This takes place by lamination either in a vacuum laminator, a vacuum press or an autoclave. In any event, a lower mold in which the shaping is performed is necessary. In a press, a convex upper mold is also necessary. In a way corresponding to FIGS. 23 and 24, plates that may be used as a deformable plate (in the sense of the patent claim: as a carrying layer) that later provides the stiffness of the solar module are composite plates which enclose between at least two thin metal sheets (aluminum, aluminum alloys) at least one core of plastic (polypropylene, polyamide), which softens under the temperature of the process to such an extent that shaping can be performed with the aid of the pressure of the process, the form that is brought about being substantially retained after the laminate has cooled down. To achieve the final intended curvature, allowance for the recovery is made in the deformation. Also pressed into the form at the same time in this process are a transparent film of plastic as the outer layer 330 (for example PC, PET, PMMA; FEP, ETFE, etc.), at least two films of hotmelt adhesive 322, 326 (for example PVB, EVA, TPU, SentryGlas®Plus (SentryGlas® is a registered trademark of the DuPont company) or Surlyn® (Surlyn® is a registered trademark of the DuPont company), between which at least one solar cell 324 and possibly a strip of glass mat are located, the films of hotmelt adhesive softening to such an extent that a laminate of the aforementioned films of plastic and the composite plate 310 is obtained. The lower mold and the upper mold may have a device with which they can be separately heated. As already described above, the composite plate 310 may be made up of a number of different layers of metal and plastic.

The invention is not restricted to the exemplary embodiments specified. For instance, it is possible in particular to combine the features of the various exemplary embodiments with one another, so that such arrangements are also comprised by the invention.

In principle, the vehicle surface components and roof modules represented form vehicle components that are given by way of example, the outer skin of which in each case forms the outer surface of the vehicle. However, the invention can also be advantageously implemented on other vehicle components, such as for example rear modules and front or rear spoilers.

List of designations

| | |
|---|---|
| 1 | vehicle |
| 2 | front windshield |
| 3 | rear windshield |
| 4 | vehicle roof |
| 5 | roof module |
| 6 | vehicle surface component |
| 7 | bead of adhesive |
| 8 | roof frame |
| 9 | flange region |
| 10 | first inner carrying layer |
| 11 | core layer (spacer layer) |
| 12 | second outer carrying layer |
| 13 | decoupling layer |
| 14 | outer skin |
| 15 | insert |
| 16 | solar cell arrangement |
| 17 | adhesive layer |
| 18 | solar cell |
| 19 | upper EVA film |
| 20 | lower EVA film |
| 21 | film |
| 22 | layer |
| 23 | depression |
| 24 | peripheral gap |
| 25 | flank |
| 26 | seal |
| 27 | adhesive |
| 28 | seal |
| 29 | sealing cord |
| 30 | sealing compound |
| 31 | sealing strip |
| 32 | sealing lip |
| 33 | peripheral region |
| 34 | roof shell |
| 101 | outer layer |
| 102 | layer of hotmelt adhesive |
| 103 | solar cell |
| 104 | electrical connectors |
| 105 | separating layer (glass mat) |
| 106 | layer of hotmelt adhesive |
| 107 | rear covering layer |
| 108 | layer of hotmelt adhesive |
| 109 | carrying layers (composite |
| | lightweight component) |
| 110 | precomposite (prelaminate) |
| 111 | outer layer |
| 112 | layer of hotmelt adhesive |
| 113 | solar cell (thin film) |
| 114 | carrier layer (for 113) |
| 123 | solar cell (thin film) |
| 124 | carrier layer (for 123) |
| 141 | layer of plastic |
| 142 | solar assembly |
| 143 | carrier |
| 200 | outer layer |
| 202 | connecting layer |
| 204 | solar cell arrangement |
| 206 | separating layer |
| 208 | connecting layer |
| 210 | metal layer |
| 212 | layer of plastic (spacer layer) |
| 214 | metal layer |
| 216 | layer of plastic (spacer layer) |
| 218 | metal layer |
| 220 | sandwich structure |
| 222 | (upper) outer layer |
| 224 | honeycomb layer |
| 226 | (lower) outer layer |
| 300 | upper mold |
| 310 | composite plate |
| 312 | outer layer |
| 314 | spacer layer |
| 316 | outer layer |
| 320 | solar cell module |
| 322 | hotmelt adhesive |
| 324 | solar cells |
| 326 | hotmelt adhesive |
| 330 | outer layer |
| 340 | lower mold |
| 350 | mold carrier |

1. A vehicle surface component,
which can be attached to a vehicle in an exterior arrangement and has a solar cell arrangement,
which is connected to a carrying layer and is provided toward the outer side of the vehicle with an outer layer,
characterized
in that the carrying layer is produced in the manner of a composite lightweight construction as a multilayer composite component,
and in that the solar cell arrangement is formed together with a transparent front covering layer and a rear covering layer as a laminar structure.

2. (canceled)

3. The vehicle surface component of claim 1,
characterized
in that the carrying layer is produced as a sandwich composite component.

4. The vehicle surface component of claim 3,
characterized
in that the sandwich composite component has a honeycomb structure with walls delimiting the honeycombs and cavities lying between the walls.

5. The vehicle surface component of claim 1,
characterized
in that the carrying layer has at least one layer with a separating layer.

6. The vehicle surface component of claim 5,
characterized
in that the separating layer consists of a glass mat or similar material.

7. The vehicle surface component of claim 1,
characterized
in that the carrying layer has at least one layer of a sheet-like plate or film which at least partially consists of metal and/or of plastic and/or of wood and/or of paper or of paperboard.

8. The vehicle surface component of claim 1,
characterized
in that the carrying layer has at least one layer of polyurethane (PU).

9. The vehicle surface component of claim 1,
characterized
in that the carrying layer is prefabricated and the solar cell arrangement is attached, and in particular adhesively attached, on said layer.

10. The vehicle surface component of claim 1,
characterized
in that the carrying layer is prefabricated with an outer surface-area depression and the solar cell arrangement is fitted in the depression in particular such that it is flush with the adjacent surface of the vehicle surface component.

11. The vehicle surface component of claim 1,
characterized
in that at least part of the carrying layer is produced by a plastics spraying process, a plastics spraying-pressing process or a plastics injection process, in particular by the Composite Spray Molding process (CSM) and/or by the Reaction Injection Molding process (RIM) and/or by the Long Fiber Injection process (LFI).

12. The vehicle surface component of claim 1,
characterized
in that the outer layer is formed by a thin glass sheet or a transparent sheet of plastic or film of plastic.

13. The vehicle surface component of claim 1,
characterized
in that the solar cell arrangement is connected to the outer layer and/or to the carrying layer by at least one layer of hotmelt adhesive.

14. (canceled)

15. The vehicle surface component of claim 1,
characterized
in that the vehicle surface component can be used for roof modules without opening systems, for roof modules with opening systems such as sliding roofs, sliding/lifting roofs, panoramic roofs, spoiler roofs, lamella roofs, retrofitted roofs, for covers of roof opening systems, for roof shells of roofs for hardtop convertibles (RHTs), for draft deflector strips, for spoilers, for rear lids, for engine hoods, for doors or fenders as well as for A, B, C and D pillar coverings.
